(19) United States
(12) Patent Application Publication
(10) Pub. No.: US 2024/0204783 A1
(43) Pub. Date: Jun. 20, 2024

(54) COMPUTATIONAL TEMPORAL LOGIC FOR SUPERCONDUCTING LOGIC CIRCUIT DESIGN

(71) Applicants: THE REGENTS OF THE UNIVERSITY OF CALIFORNIA, Oakland, CA (US); University of Maryland, College Park, College Park, MD (US)

(72) Inventors: Georgios Tzimpragos, San Jose, CA (US); Dilip Vasudevan, Emeryville, CA (US); Nestan Tsiskaridze, Santa Barbara, CA (US); Georgios Michelogiannakis, Berkeley, CA (US); Advait Madhavan, Gaithersburg, MD (US); Jennifer Volk, Santa Barbara, CA (US); John Shalf, Oakland, CA (US); Timothy Sherwood, Goleta, CA (US)

(21) Appl. No.: 17/909,932

(22) PCT Filed: Mar. 3, 2021
(86) PCT No.: PCT/US2021/020695

§ 371 Date: Sep. 7, 2022

Related U.S. Application Data
(60) Provisional application No. 62/987,203, filed on Mar. 9, 2020.

(51) Int. Cl. H03K 19/195; H03K 3/037; H03K 19/20

(52) U.S. Cl. CPC H03K 19/195; H03K 3/037; H03K 19/20

(57) ABSTRACT

A primitive race-logic temporal operator is described, comprising superconducting logic single flux quantum (SFQ) cells.

### CROSS-REFERENCE TO RELATED APPLICATIONS

This application claims the benefit under 35 U.S.C. § 119(e) of U.S. Patent Application No. 62/987,203, filed on 9 Mar. 2020, the entire contents of which is hereby incorporated by reference herein.

### STATEMENT OF GOVERNMENT SUPPORT

This invention was made with government support under Contract No. DE-AC02-05CH11231 awarded by the U.S. Department of Energy, under Contract No. 70NANB14H209 awarded by the National Institute of Standards and Technology, and under Agreement No. 1763699 awarded by the National Science Foundation. The government has certain rights in this invention.

### FIELD

The present invention relates to the superconducting logic circuit design and more particularly, relates to computational temporal logic for superconducting logic circuit design.

### BACKGROUND

Superconductivity is the phenomenon wherein the electrical resistance of a material approaches zero as it is cooled to below a critical temperature. Computing with such superconducting materials continues to be the subject of research.

### BRIEF DESCRIPTION OF THE DRAWINGS

FIG. 1 illustrates CMOS race logic implementation functionality, according to one embodiment.

FIG. 2 illustrates an example first arrival gate block diagram and an example inhibit gate block diagram, according to one embodiment.

FIG. 3 illustrates example RSFQ implementations (circuits) of our temporal operators, state diagrams, and functionality, according to one embodiment.

FIG. 4 describes an example data-driven self-timing (DDST) scheme, according to one embodiment.

FIG. 5 illustrates LastArrival gate and spacer period functionality, according to one embodiment.

FIG. 6 illustrates example timing relationships between pulses in the described architecture, according to one embodiment.

FIG. 7 illustrates timing analysis for an Inhibit gate and provides simulation results, according to one embodiment.

FIG. 8 illustrates an example Needleman and Wunsch implementation, according to one embodiment.

FIG. 9 illustrates example simulation results for a 3×3 DNA sequencealignment problem, according to one embodiment.

FIG. 10 illustrates an example RSFQ Merge element realizing a stateless FirstArrival gate, according to one embodiment.

FIG. 11 illustrates simulation results for a statelessimplementation of a sequencing accelerator, according to one embodiment.

FIG. 12 illustrates decision tree implementations, according to one embodiment.

FIG. 13 illustrates decision tree of FIG. 12 simulation results, according to one embodiment.

FIG. 14 illustrates example specifications, architectures, and simulations of an example feedforward temporal network implementing an arbitrary function table, according to one embodiment.

FIGS. 15-21 illustrate example circuit implementations, according to one embodiment.

### DETAILED DESCRIPTION

Superconductivity is the phenomenon wherein the electrical resistance of a material disappears as it is cooled below a critical temperature. Superconductivity was discovered in 1911 by K. Onnes, who observed that the resistance of solid mercury abruptly disappeared at the temperature of 4.2K. Four decades later, D. A. Buck demonstrated the first practical application of this phenomenon—the cryotron—and soon after, B. Josephson established the theory behind the Josephson effect, which led to the fabrication of the first Josephson junction (JJ) in the subsequent years.

In one embodiment, a JJ may be made by sandwiching a thin layer of non-superconducting material—an electronic barrier—between twolayers of superconducting material. JJs may be capable of ultrafast (as low as 1 ps), low-energy (to the order of 10⁻¹⁹J) switching by exploiting the Josephson effect: electron pairs tunnel through the barrier without any resistance up to a critical current. At the critical threshold, a JJ switches from its superconducting state to a resistive one and exhibits an electronic “kickback” in the form of magnetic quantum flux transfer—observable as a voltage pulse on the output. To enable stateful circuit operation, the unit of flux can be temporarily stored in a composite device known as the superconducting quantum interference device (SQUID), which is built as a superconducting loop interrupted by two serial JJs and is common to many superconducting circuits.

Over the years, several ambitious designs of superconducting ALUs and microprocessors have been presented in an effort to capitalize on the promise of superconductors. The majority of these implementations are primarily based on simplified architectures, bit-serial processing, and on-chip memories realized with shift-registers. Bit-serial processing has been selected over bit-parallel approaches due to its lower hardware cost and complexity. However, this design choice may compromise the advantage speed of SFQ technology as the number of execution cycles per instruction increases with the number of bit slices. Moreover, the use of shift register-based memories—given the lack of dense, fast, and robust cryogenic memory block—seems to be the only reasonable choice at the moment; which is still possibly not a viable solution though for large-scale designs.

More recently, interest has increased in the development of superconducting computing accelerators. Due to the lack of sophisticated design tools and the limited device density and memory capacity in superconducting technology, applications with tiny working set sizes and high computational intensity may be suited for JJ-based accelerators. As a proof-of-concept, RQL-based accelerator was developed for SHA-256 engines, achieving 46× better energy-efficiency than CMOS. To improve the critical path and the overall energy efficiency of the implementation, an optimization focus was on two components of the SHA engine: adders and registers.

In another stochastic computing-based deep learning acceleration framework embodiment, stochastic computing's time-independent bit sequence value representation and small hardware footprint of its operators may be leveraged to redesign the basic neural network components in AQFP. Such embodiment may be shown to achieve order of magnitude energy improvements compared to CMOS. However, the known drawbacks of stochastic computing (e.g., the calculation accuracy, expressiveness, and performance of stochastic computer circuits depend on the length and correlation of used bit-streams) raise number of questions regarding the suitability and efficiency of this method for more general tasks or for precise computing applications.

While these implementations succeed at demonstrating the potential of superconducting computing, the question of “what a more general superconducting design methodology would look like?” was still pending. To get a better understanding of the reasons that make superconducting computing so challenging a good idea may be to take a step back and look closer at the fundamentals of this technology as well as its main differences from CMOS.

In contrast to CMOS, where an “1” is represented by a steady voltage level in hundreds of millivolts, in SFQ, picosecond-duration, millivolt-amplitude pulses are used. Moreover, SFQ comes with a different set of active (JJs) and passive (inductors) components and interconnection structures (Josephson Transmission Lines and Passive Transmission Lines) than CMOS. Clock distribution and synchronization may also be concerns as each Boolean SFQ logic gate has to be driven by a synchronous clock and all input pulses need to be aligned.

Given the difficulties that existing approaches face and the unique characteristics of superconducting technology, the most promising way forward is to come up with innovative computing paradigms and circuit architectures that (a) use much fewer JJs than transistors for the same information processing, (b) have low memory requirements, (c) allow for easier clocking, and (d) can cover a wide range of applications

Computing with such superconducting materials offers the promise of orders of magnitude higher speed and better energy efficiency than transistor-based systems. Unfortunately, while there have been tremendous advances in both the theory and practice of superconducting logic over the years, significant engineering challenges continue to limit the computational potential of this approach. In contrast to semiconductor logic, where logic cells are combinational and their output is (to first order) a pure function of the levels of all the inputs present at any time, the majority of Single Flux Quantum (SFQ) logic gates are sequential and operate on pulses rather than levels. Because pulses travel ballistically rather than diffusively through a channel, once they have transited there is no “record” of their value that can be used in downstream computations. Implementing a chain of Boolean operations thus may require a very careful layout and synchronization of timing along each and every path with picosecond-level precision.

While some of the challenges in adopting such a novel technology are inherent to the nature of the exotic materials and environment, others appear to be due to a mismatch between our computational abstraction and what the devices actually provide. Because many superconducting logic designs rely on discrete voltage pulses driven by the transfer of magnetic flux quanta, supporting the combinational abstraction provided by traditional logic requires significant design effort and results in unavoidable overheads. If these pulses are instead thought of as the natural representation of data in a superconducting system, the natural language for expressing computations over that data would be one that could precisely and efficiently describe the temporal relationships between these pulses. Here, one may draw upon two distinct lines of research, both currently disconnected from superconducting.

Some embodiments show that delay-based encoding has both impressive computational expression and practical utility in implementing important classes of accelerators—not to mention the interesting connections to neurophysiology. The principles of the delay-coded logic apply directly to problems in superconducting. However, the fact that its primitive operators have been so far implemented only in CMOS under specific assumptions—e.g., edges are used to denote event occurrences—makes their realization in the much different Rapid SFQ (RSFQ) technology potentially challenging.

In one embodiment, the long history of work in temporal logic used for expressing temporal relationships in reasoning and verification may be leveraged. While temporal logic systems (e.g. Linear Temporal Logic) deal with the relationship of events in time, they are fundamentally predicate logics that allow one to evaluate truth expressions (True/False) over some set of temporal relationships. A temporal logic with computational capabilities that takes events as inputs and creates new events as outputs based on the input relationships is thus desirable.

Advantageously, a new computational temporal logic (which in fact subsumes LTL) is described herein that gives clear, precise, and useful semantics to delay-based computations and relates them to existing temporal logics. This approach allows for a trade of implementation complexity for delay, realization of superconducting circuits that embody this new logic, and a creation of useful new architectures based on these building blocks that encapsulate the potential of those circuits.

To overcome the issues described above and others, the embodiments described herein are provided. In one embodiment, classical temporal predicate logic is extended to a computational temporal logic to formally express delay-based computations. This extension provides the needed abstractions to capture the capabilities of new operators and it sets the foundation for the construction, analysis, and evaluation of large-scale temporal systems.

In another embodiment, examples circuits are provided that implement these primitive temporal operators in RSFQ and evaluate their functionality and performance with SPICE-level simulations. A method of combining these temporal operators into larger self-timed superconducting accelerator architectures is also provided. The data-driven self-timing approach described herein enables the operation of RSFQ designs without the need of clock trees even in the most general case.

In another embodiment, the presented hypothesis is validated through (a) a functional verification of three RSFQ accelerators at the SPICE level, (b) a performance comparison between superconducting designs described herein and their CMOS counterparts—showing more than an order of magnitude performance improvements—and (c) a timing analysis necessary to identify timing constraints that may affect the design flow of superconducting temporal accelerators.

Superconducting SFQ technologies are a promising candidate for high-speed and ultralow-energy operation for certain classes of computation. Though both theunderlying physics and basic circuit technologies are well understood, many hurdles remain before larger computations can enjoy the benefits of superconducting materials.

Described herein isanewfoundation thatbridges the gap between the level-driven logic traditional hardware designs acceptas a foundation and the pulse-driven logic naturally supported by the most compelling superconducting technologies. The harmonious interaction between three different areas of work—superconducting logic, temporal predicate logic, and delay—based codes is advantageous in a variety of contexts. As demonstrated, superconducting logic can naturally compute over temporal relationship between pulse arrivals. Implementation circuits for fundamental operators in temporal logic are provided. An asynchronous data-driven self-timing scheme is described and a timing analysis to identify timing constraints that affect the design flow of superconducting temporal accelerators is illustrated. Advantageously, three temporal accelerators are implemented in RSFQ and their performance is compared against their CMOS counterparts, showing more than an order of magnitude improvements.

### Race Logic

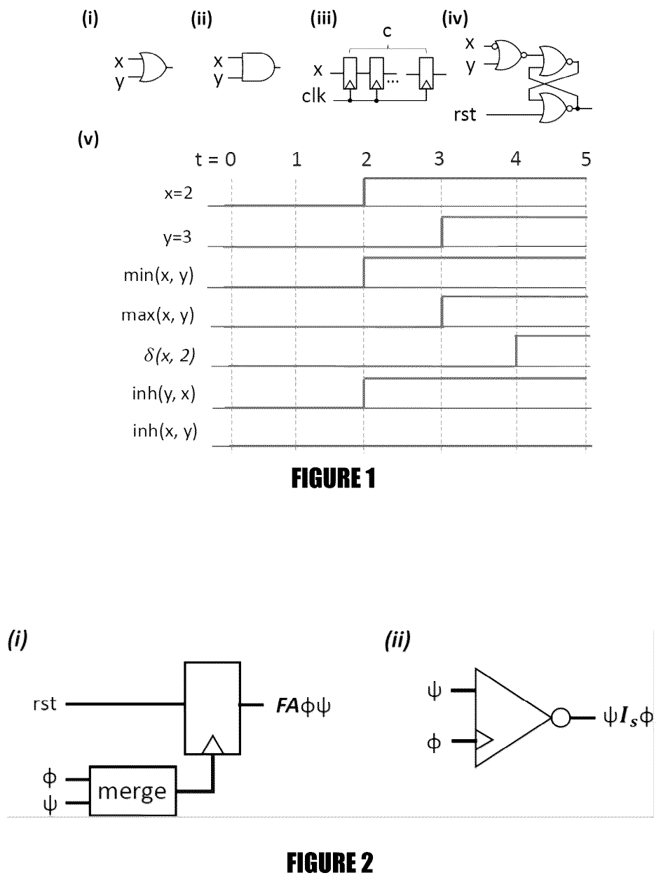

FIG. 1 illustrates race logic implementation functionality implemented in CMOS (prior art), according to one embodiment. In one embodiment, race logic may be used to encode information in the timing of events rather than the amplitude of voltage levels. Events may be represented by low to high edges and computation emerges through the purposeful interaction of these edges and their relative delays. In one embodiment, the time it takes for an event to appear on a wire is what encodes the value. Thus, only a single wire may be needed per variable.

In one embodiment, the operators forming the foundation of race logic are Min (FirstArrival), Max (LastArrival), Add-Constant (Delay), and Inhibit. FIG. 1 shows the implementation of these four primitives with traditional CMOS components. Prior to the next computation, race logic-driven circuitry must be reset.

Referring to FIG. 1, panels (i), (ii), (iii), and (iv) show the implementation of Min, Max, Add-Constant, and Inhibit functions in race logic with off-the-shelf CMOS components. Panel (v) provides an example waveform for x=2 and y=3.

Regarding its applicability, race logic yields a complete implementation of space-time algebra, which provides a mathematical underpinning for temporal processing. Any function that satisfies the properties of invariance and causality complies with space-time algebra, and thus it is implementable in race logic. In one embodiment, race logic may be used to implement Needleman and Wunsch's DNA sequence algorithm. A low-cost bitonic sorting network circuit may be demonstrated using temporal processing. Race logic may be demonstrated to accelerate ensembles of decision trees, while the relationship between temporal codes and spiking neural networks may be explored.

In one embodiment, the implementation of this new paradigm, where the order of events occurrence defines computation, is tied to specific assumptions and the properties of the underlying CMOS technology, which in some cases may restrict innovation. For example, as discussed above, when edges are used for event representation, M_{IN} and M_{∧X} functions can be realized with plain OR and AND gates. What happens though when edges are replaced by pulses, as in the superconducting case? To answer this question and establish a theoretical foundation that will allow for a better understand of how processing in the temporal domain can unlock the true potential of emerging technologies, this logic's formalization is provided herein.

### Formalization

In one embodiment, computing based on temporal relationships may depart from traditional binary encoding and Boolean logic and may provide a promising pathway for unlocking the true potential of emerging technologies. To make this computing paradigm a viable solution the first question that should answer is “what abstractions do we need to establish in order to capture its capabilities, verify the correctness of temporal implementations independently of underlying assumptions and technology properties, and build more complex temporal circuits in a systematic way?”

To solve this problem and set the foundation for the design and evaluation of large-scale temporal systems, in this section, formal definitions of its primitive operators and constraints through an extended temporal logic capable of concisely expressing delay-based computations are provided.

### Computational Temporal Logic

Space-time algebra defines the primitive operators of generalized race logic over the set of Natural numbers, and thus provides a high-level abstraction to the event-based computation happening at the circuit-level. This abstraction may in some cases be useful for functional interpretation or synthesis; however, it may not capture lower-level details that may be critical for the hardware implementation and reasoning of such systems. Described herein is a formalization that covers this gap and safely decouples functional from implementation specifications.

Temporal logic is a tool that may be used for representing and reasoning about propositions qualified in terms of time; e.g., an event in a system S has happened or will happen sometime in the past or future. A system S transitions through a sequence of states in time, where each state St is associated with a time step t belonging to a discrete time domain. Properties are then expressed as formulas and are evaluated along such sequences of states. Formulas are constructed recursively from propositional atoms by applying usual propositional connectives ¬, ∨, ∧, →, ↔ and the additional temporal logic operators discussed below.

In the well-established setting of Linear Temporal Logic (LTL), the future-time temporal operators are used: ⋄ sometime in the future, □ always in the future, ◯ next time (tomorrow), U until, and R release. Past LTL (PLTL) extends LTL with past-time operators, which are the temporal duals of the future-time operators, and allows one to express statements on the past time instances, such as: ♦ sometime in the past, ▪ always in the past (historically),—previous time (yesterday), S Since, and T Trigger. Even though the past-time operators do not add expressive power in the sense that any LTL formula with past operators can be rewritten by only using the future-time temporal operators, the past-time operators are particularly convenient in practice; they allow one to keep specifications more intuitive and easy to comprehend, and they can provide significantly more compact representations than their future-time counterparts.

Each operator operates on a sequence of states, which defines a discrete interval of time steps—the scope of the operator. In one embodiment, these temporal operators may be categorized based on their scope at time step t as follows:
remote past operators ♦, ▮, S, T—their scope is [0, t];
immediate past operator -—its scope is {t−1}, or the empty interval if t=0;
present operator (all propositional connectives)—its scope is {t};
immediate future operator g— its scope is {t+1};
remote future operators ⋄, □, U, R—their scope is [t, ∞).

In one embodiment, the scope of an arbitrary formula ϕ is defined recursively based on the scopes of the operators in ϕ and the given time step t.

In LTL, the notation <S, t>may be used to signify a system S at a time step t. An event ϕ occurs at time step t in the system S if ϕ holds at time step t in S, demoted by <S, t>|=ϕ. As described herein, the formal semantics of the ♦ operator (sometime in the past) may be primarily relied upon:

(S,t)|=♦ϕiff∃k. (0≤k≤t∧(S, k)|=ϕ)

This definition reads as: the temporal formula ♦ϕ holds at time step t in the system S if and only if there exists a time step k prior or equal to t when the formula ϕ holds. However, this operator is incapable of encapsulating when ϕ held in the past, which is essential for our case. To address this issue, the earliest-occurrence function is described below.

Let ∞ be a special symbol that represents an unreachable time step; in other words, ∞ indicates the lack of an event occurrence in a period of interest. The earliest-occurrence function E_{St} (ϕ) receives as input a formula ϕ and returns the earliest time step tₘᵢₙ (s,t), where (s,t) is the scope of ϕ at time step t in the system S, such that (S, tₘᵢₙ)=ϕ. If ϕ does not hold at any time step within (s,t), then the earliest-occurrence function returns. The formal definition of this function follows:

$${E}_{( S , t )} ( ϕ ) = \begin{matrix}▯ ▯ & {t}_{min} & \begin{matrix}( {t}_{min} ∈ {[ [ ϕ ] ]}_{( S , t )} ∧ ( 〈 S , {t}_{min} 〉 \vert = ϕ ) ⋀ \\ \hat{} ( ∀ j \cdot O \leq j < {t}_{min} : 〈 S , {t}_{min} 〉 □ \vert = ϕ )\end{matrix} \\ ▯ ▯ & ∞ , & otherwise .\end{matrix}$$

The proposed function is paired with the existential primitives of the classical temporal logic, extends the notions of “sometime in the past” and “sometime in the future” with the notion of “when” an event occurred, and it is fundamental for the connection of event-based formalization, which is presented next, with the existing space-time theory.

### Race Logic Semantics

In one embodiment, according to space-time algebra, FirstArrival (FA), Inhibit (IS), and Delay (D) operators are functionally complete for the set of space-time functions. In prior work, the functionality of these operators at the event-level has been primarily described through their realization with off-the-shelf CMOS components under the assumption of an edge-based delay encoding. In this work, we decouple for the first time their specification from their implementation and provide a formal definition, presented in Table 1, using the above-described computational temporal logic. Moreover, besides these three basic operators, definitions for LastArrival (LA) and Coincidence (C) operators are provided, which have been widely used in a number of accelerators.

TABLE 1
PLTL-based semantics of the operators FirstArrival (FA),
StrictInhibit (IS), Delay (D), LastArrival (LA), and Coincidence (C).

[symbol]

S, t [symbol] |= FAϕψ iff [symbol] S, t [symbol] |= ♦ϕ ∨ ♦ψ [symbol]
S, t [symbol] |= ψIsϕ iff ∃k. (O ≤ k ≤ t ∧ [symbol] S, k [symbol] |= ϕ ∧ ¬♦ψ); [symbol]
S, t [symbol] |= Dcϕ iff ∃k. (O ≤ k + c ≤ t ∧ [symbol] S, k + c [symbol] |= ♦ϕ); [symbol]
S, t [symbol] |= LAϕψ iff [symbol] S, t [symbol] |= ♦ϕ ∧ ♦ψ ; [symbol]
S, t [symbol] |= Cϕψ iff ∃k. (O ≤ k ≤ t ∧ [symbol] S, k [symbol] |= ϕ ∧ ψ) ∧
∧ ∀j.(O ≤ j < k ∧ [symbol] S, j [symbol] ▭|= ♦ϕ ∨ ♦ψ );

Informally, Table 1 reads as follows:
FA: the formula FAϕψ holds at time step t in system S if and only if either ϕ or ψ hold at time step t or prior.
I_{S}: the formula ψ I_{S}ϕ holds at time step t in system S if and only if there exists a time step k prior or equal to t when ϕ holds and ψ does not hold at this and any prior time steps.
D: the formula Dcϕ holds at time step t in system S if and only if there exists a time step k+c prior or equal to t when ϕ holds at this (c=0) or any prior time steps (cÇ0).
LA: the formula LAϕψ holds at time step t in system S if and only if both ϕ and ψ hold independently at time step t or prior.
C: the formula Cϕψ holds at time step t in system S if and only if there exists a time step k prior or equal to t when both ϕ and ψ hold simultaneously and there are no prior time steps where either ϕ or ψ will hold.

These definitions provide a PLTL-based specification of the basic race logic operators over temporal events; however, they will always return a proposition: True or False. To extract the step at which these functions evaluate to True for the first time in their scope the above-introduced earliest occurrence function E(_{s,t}) (ϕ) may be used. For example, E(S,t) (FAϕψ) will return the first time step that either ϕ or ψ will hold.

In summary, the presented formalism, along with the proposed extension to the classical temporal logic: (a) guarantees that the specification of our operators is independent of any underlying assumptions; e.g., pulse- vs edge-based encoding, (b) bridges the gap between the high-level definitions provided by space-time algebra and the event-based computing happening at the implementation level, and (c) opens up the door to the use of model checking tools for the formal analysis, validation, and optimization of more complex temporal circuit designs.

### Superconducting Temporal Architecture

In one embodiment, the mathematical formalism raised with respect to the formalism description above lays the foundation for building and verifying the desired temporal operators. In this section, their implementation in RSFQ is described, and the corresponding circuit simulation results are provided, and finally a self-clocked RSFQ architecture that alleviates the clock distribution and skew problems met in traditional digital designs ported from CMOS to the RSFQ world is described.

### Temporal Primitives in RSFQ

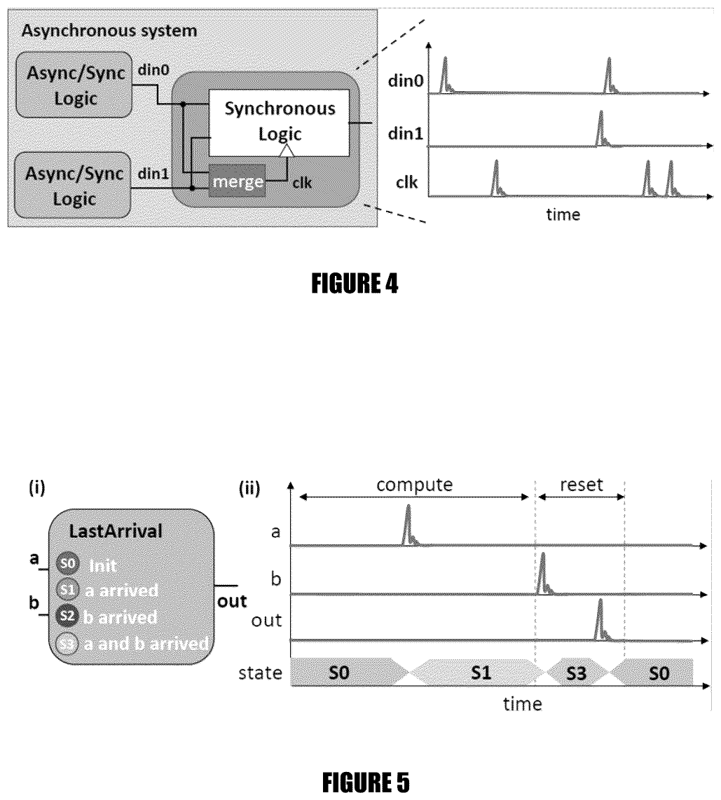

In one embodiment, the way in which events are encoded plays an important role in selecting the hardware that most efficiently implements logic operators. For example, given the conventional rising edge-based realization of events, FIRSTARRIVal and LASTARRIVal functions can be implemented with a single OR and AND gate, respectively. As shown in FIG. 1, an OR gate fires when its first high input arrives, while an AND gate fires only when all its inputs are “1”. An important property of edge-based event encoding is that it automatically keeps track of the input state at all times—a signal that has made a transition from a “low” to “high” state will not make a transition back to a “low” state in the same computation. This feature may break down when dealing with pulses. Pulses naturally return back to their “low” state, preventing downstream nodes from implicitly knowing the state of its predecessors. To address this issue we propose embedding the state into each gate, instead of relying on the input to “hold” state. Interestingly, the majority of RSFQ elementary cells have both logic and storage abilities, and thus they provide several unique design opportunities. In FIG. 3, the schematics of example circuit designs are illustrated, along with Mealy machines describing their operation, and WRSPICE simulations showing their functionality. A detailed description of their implementation also follows.

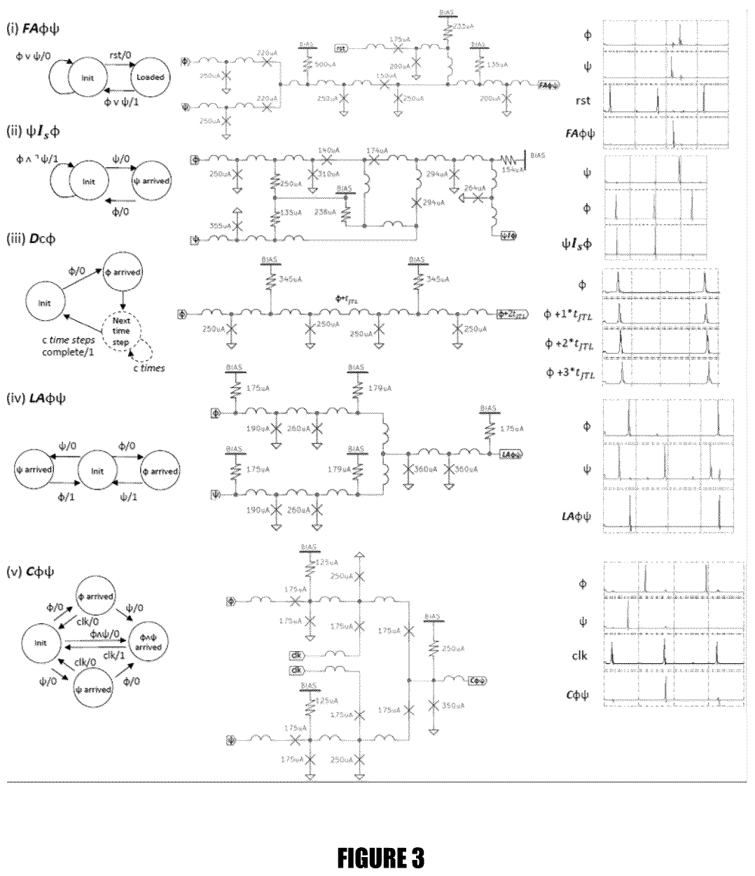

According to its formal definition, the FIRSTARRIVal gate FA emits an output pulse when its first input arrives. For its implementation in RSFQ, a MERGE element along with a D FLIP-FLOP are used—see FIG. 2 (i) and FIG. 3 (i). Referring to FIG. 2: FIRSTARRIVal gate is built out of a MERGE element and a D FLIP-FLOP; a reset signal rst is connected to the D FLIP-FLOP's data input, while the output of the MERGER serves as its clock signal. Panel (ii): to implement INHIBIT a latching INVERTER is used; the data signal ϕ serves as the INVERTER'S clock signal and the inhibiting signal ψ as its data signal.

In one embodiment, a MERGE element can be thought of as a non-latching OR gate that produces an output SFQ for each incoming pulse from any of its input ports. However, in race logic, at most one event is allowed to occur per “wire” across the entire computation. To ensure that all but the first arriving pulses will be filtered out a D FLIP-FLOP may be used. A D FLIP-FLOP is built around a direct current (DC) SQUID and has two stable states: Init and Loaded, which correspond to the lack or presence of a flux quantum, respectively. When a data signal arrives at its input port the latch switches to/remains in the Loaded state and returns to the Init state only when a clock signal is received. When transitioning from Loaded to Init the flux quantum stored in the quantizing SQUID loop is released; thus, an output pulse is emitted and the quantizing loop gets cleared. While in state Init, a clock pulse will not cause any state change or output activity. So, to achieve the desired functionality a reset signal rst may be connected to the D FLIP-FLOP's data “in” port, while the output of the M_{ERGE} element plays the role of the clock signal.

In one embodiment, the INHIBIT operator Iₛ may receive two input signals: one for the inhibiting signal ψ and one for the data signal ϕ. As described in Section 2.2, an output pulse is emitted only if ϕ arrives before ψ. To implement INHIBIT in RSFQ a single INVERTER may be used—see FIG. 2 (ii) and FIG. 3 (ii). According to the INVERTER's specification, if a data pulse arrives, the next clock pulse reads out “0”; otherwise, it reads out “1”. Thus, if a signal ϕ is routed to the inverter's clock port and ψ to its data port, this component will act exactly as an INHIBIT operator in the logic.

In some SFQ circuits, Josephson Transmission Lines (JTLs) may be used for the interconnection of logic cells over short distances. More specifically, a JTL is a serial array of superconducting SQUIDs and operates in the following way. Because magnetic flux cannot be absorbed or dissipated by a superconducting circuit, an incident flux quantum is only allowed to pass along the JTL and does so by switching each JJ in turn. In our case, these interconnection structures are not used just for pulse transmission purposes but also realize our DELAy operator D—FIG. 3 (iii). As described earlier, delaying a race logic event by a fixed amount of time corresponds to CONSTant ADDITION. For the implementation of the LASTARRIVal gate, a C-element is used—FIG. 3 (iv). A C-element has two input ports and consists of two SQUIDs. In the circuit's initial state, no persistent superconducting current is present in the quantizing loops. When an input arrives, the corresponding junction gets triggered but the generated pulse is not sufficient to trigger an output pulse. When the second input pulse arrives, the total current exceeds the threshold of criticality, an output pulse gets emitted, and the element returns to its initial state. The order of input pulse arrivals does not matter.

Finally, a COINCIDENCE gate is supposed to fire only if its inputs arrive “simultaneously”. In edge-based implementations, a COINCIDENCE gate is composed of FA, LA, Iₛ, and D gates. In the pulse-based superconducting logic though, a single RSFQ AND gate is all that may be needed to implement COINCIDENCE—FIG. 3 (v). As known, an RSFQ AND gate produces an output pulse only if both its input pulses arrive within the same cycle; thus, it performs in an easy way the desired functionality.

Referring to FIG. 3: Panel (i): FIRSTARRIVal FAab. Panel (ii): strict INHIBIT aI_{S}b. Panel (iii): DELAY Dca, where t _{JT L} is the delay that each JTL causes. Panel (iv): LASTARRIVal LAab. Panel (v): COINCIDENCE Cab.

Area and latency results for each of these operators are pro-vided in Table 2. The shown estimates are based on WRSPICE simulations using the MIT-LL SFQSee 10 kA/cm² process.

TABLE 2
Area and latency results for temporal operators implemented in
the MIT-LL SFQ5ee 10 kA/cm² process and simulated with WRSPICE.

| Function | Area (#JJs) | Latency (ps) |
|---|---|---|
| FA | 10 | 13 |
| Iₛ | 8 | 11 |
| D | 2/JTL | 5/JTL |
| LA | 6 | 8 |
| C | 11 | 9 |

### Self-Clocked Temporal RSFQ Circuits

Clocking and synchronization are two of the concerns and limitations in the design process of an RSFQ design. The majority of RSFQ Boolean gates are sequential in nature. Hence, each gate in a Boolean RSFQ circuit needs to be synchronized with all other gates and the clock network. The complexity and overhead introduced by the clock network are far from negligible, primarily because an additional SPLITTER is required for each latched gate for clock fan-out. These additional SPLITTERs affect a design both in terms of area (3 JJs per element) and speed (each SPLITTER introduces a delay on the order of a single JTL), while they also contribute to a higher static and dynamic current.

Moreover, device variations can promote disproportionate clock timing skews, which can critically affect the functionality of a Boolean RSFQ design; all pulses between a gate and each of its fan-in gates must arrive in the same clock cycle (as defined by the clock network). To mitigate these issues, advanced path-balancing techniques and customized RSFQ logic synthesis tools are needed.

In the superconducting temporal logic described herein, many of these concerns are naturally alleviated as FIRSTARRIVal, INHIBIT, and DELAy, which form the minimal functionally complete operator set, are asynchronous—the “clock” signal of the latching building blocks used for their realization has been repurposed, as described in Section 4.1. However, in some cases, such as COINCIDENCE, the use of a synchronous gate/block makes sense. To avoid costly clock trees and the clock skew problems that come with them, a data-driven self-timing scheme is described herein.

In a data-driven self-timed (DDST) system, timing information is carried by data. In one embodiment, data are carried by complementary signals, generated by using complementary D flip-flops; two parallel lines are required for each bit. The clock signal is generated by a logical OR function between these lines. Because each functional block is now locally clocked, there is no need for a global clock network. Therefore, the system becomes more robust to process variations and has better control over clock timing. Besides its advantages, this embodiment, may have a high cost; the method may introduce a significant overhead for routing as well as additional circuitry for generating complementary signals for each logic gate.

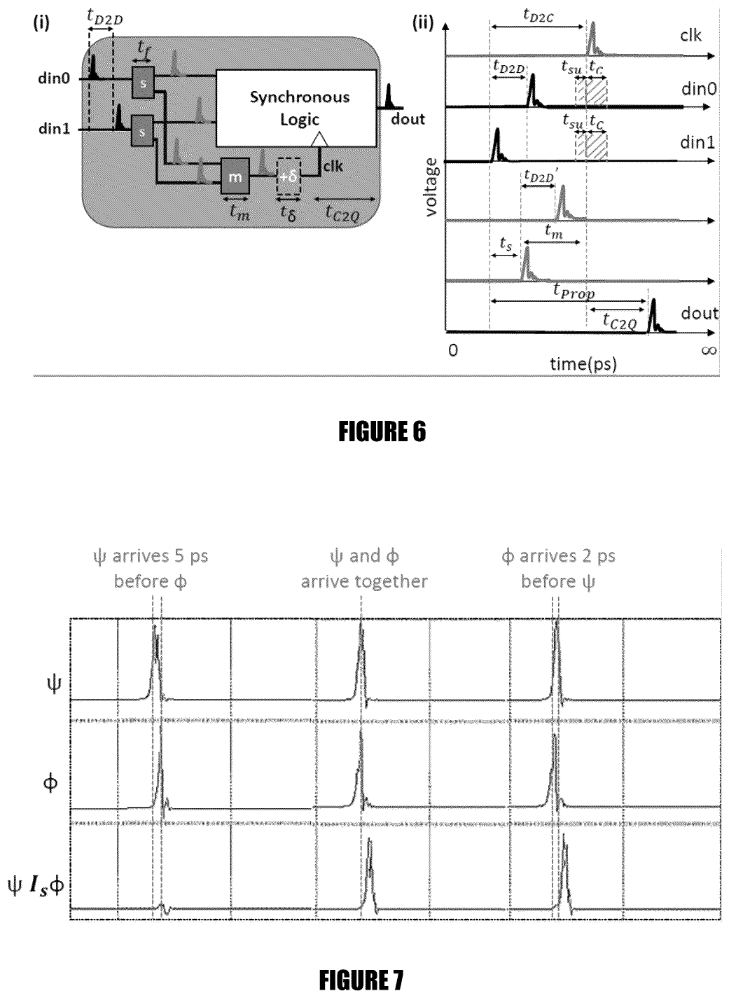

FIG. 4 describes an example data-driven self-timing (DDST) scheme. The clock signal can be locally generated from input data at each gate. If no input pulse arrives, it is safe to assume the operator is idle, and thus no clock pulse is required.

In one embodiment, the DDST method shown in FIG. 4 targets temporal rather than binary systems and is able to provide similar benefits at a much lower “price”. In contrast to Boolean logic, where for example a NOT gate has to be clocked even in the absence of an incoming pulse, when processing in the temporal domain, an operator can be safely considered idle for the time steps that no input pulse arrives. Thus, complementary data are no longer required. This characteristic of temporal codes significantly simplifies the implementation of our DDST approach, reduces its area overhead, while still allowing one to have the desired fine-grained timing control.

Resetting: Given the absence of an independent clock and the stateful nature of RSFQ operators, resetting must also be rethought. For example, an RSFQ INVERTER, which implements INHIBT, may not return to its initial state until a pulse arrives to its clock port, while a C-element, used as a LASTARRIVal gate, may not reset until both its inputs arrive. One possible solution is to add an additional reset signal to Iₛ and LA gates, merged with their input data signals; as can be seen in FIG. 3, the rest of the temporal operators return to their initial state without the need for external signals. This additional signal allows the immediate reset of such a gate but it comes with additional circuitry too. For example, the MERGER that has to be used in the case of INHIBIT may cost at least 5 JJs, while the overhead in the case of a LASTARRIVal gate may be much higher as the reset signal must be forwarded to the input ports that have not received a data pulse yet.

In one embodiment, when such a reset signal is used, the target gate may return to its initial state; however, in many cases an output pulse is generated too. This output pulse propagates through the circuit in a downstream fashion and may affect the state of other subsequent gates. So, resetting a deep temporal circuit may have to be done sequentially—one stage of gates at a time.

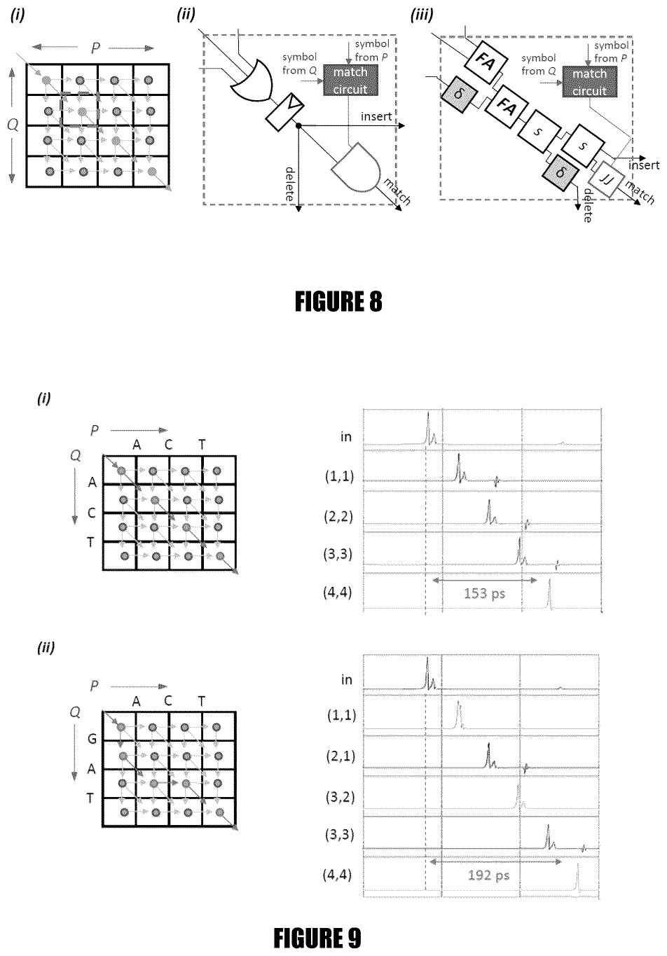

To avoid the interference of data pulses that relate to the actual computation with the ones generated by resetting, a spacer period may also be utilized. FIG. 5 illustrates this scenario for a plain LASTARRIVal gate. Once the “compute” period ends, a reset pulse is sent to its input port b. Any output pulse observed until the next compute period starts should be ignored. If the LASTARRIVal gate is connected to other gates, the generated output pulse may also affect their state even if they have already been cleared. So, resetting in that case must happen step-by-step and the duration of the spacer period will have to be adjusted accordingly.

An alternative method that may be relied upon for resetting is to adjust the amount of applied bias current; setting the applied bias current to zero will release the stored flux quanta and return the gates to their initial states. This solution does not require additional hardware and comes without the concerns related to the propagation of reset-generated pulse. However, it is still not “free.” Choosing between these two options depends on the structure of the constructed circuit, possible resource constraints, and the corresponding delay associated with each of these methods.

### Evaluation

In the previous sections, a framework for understanding the proposed RSFQ-based temporal computing paradigm at the logic, primitive gate, and device-levels has been presented. We may now leverage this understanding to functionally validate our design methodology through a number of accelerator designs. For the timing and functional validation of the developed circuits, we first identify timing constraints that affect the design flow and then provide corresponding SPICE-level simulation results. Finally, we compare their performance against their CMOS counterparts, showing more than an order of magnitude improvements.

Experimental setup: Analysis is performed based on the open-source WRSPICE circuit simulator using the MIT-LL SFQ5ee 10 kA/cm² process. For these designs' interconnections, JTLs along with SPLITTERs (s) and MERGERs (m) were used.

Timing Analysis

Computing based on temporal relationships is in many cases naturally immune to noise as the final outcome often depends on the interval or the order in which events occur and not precise arrival times. Under conventional binary encoding, an early or late pulse translates to a bit-flip and its effect on the computation's accuracy depends on the bit's position. Under delay representation though, a time-skewed pulse may or may not affect the encoded value—in reality, an interval rather than a specific time is used to represent a value—and that may not even change the rank order of the occurring events.

To ensure the robustness of the designs described herein, one should not rely solely on the properties of the encoding and temporal logic. Understanding the various timing constraints is important for reasoning about the circuits' behavior and developing a systematic way for the design of temporal RSFQ accelerators. To address this concern, in the following, we first introduce the required terminology for our timing analysis and then proceed with the description of the timing constraints of temporal circuits and the quantification of our primitives' robustness to the timing skew of pulses.

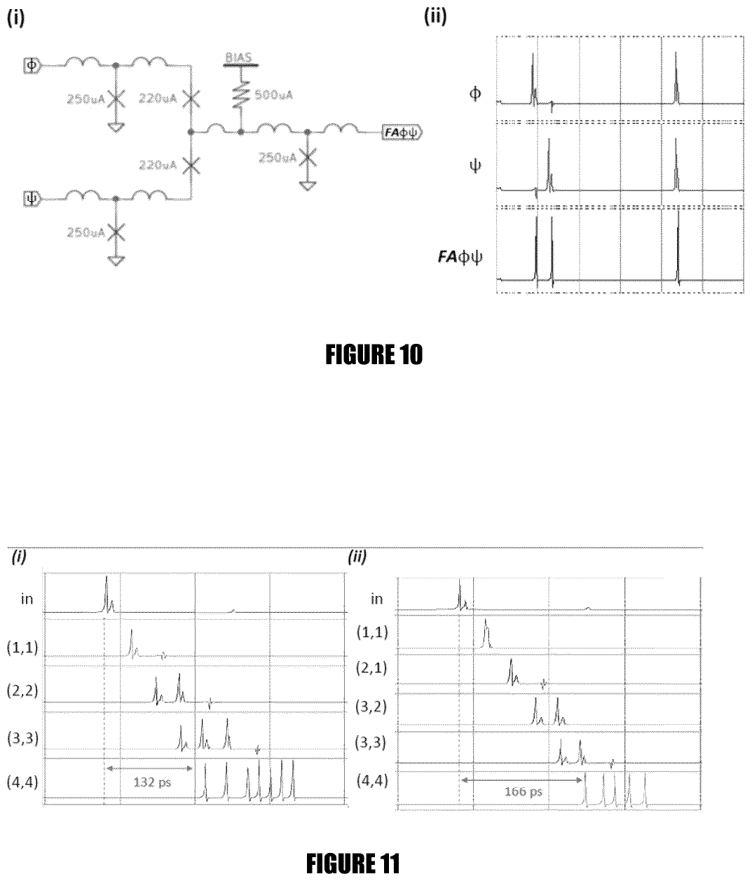

FIG. 6 provides an illustration of the main timing relationships between pulses in the described architecture. In one embodiment, FIG. 6 supports FIG. 4, where the delay element (+δ) introduced after the merger (m) stretches the input window.

Data-to-data (tD₂D) window represents the time difference between two input data signals. Clock to Q (tD₂Q) denotes the delay between clock signal arrival and the occurrence of the output event. The propagation delays of the SPLITTER and MERGER are shown as tₛ and tₘ, respectively. Finally, tₛᵤ represents the setup time, which denotes the minimum amount of time required between the arrival of data and clock signals, while t_{c} is the time window where input pulses are forbidden to arrive.

To avoid setup time violations, t_{D2D} has to be less than tₘ-tₛᵤ if the two input pulses represent the same value. To increase this time window, delay elements can be added after the M_{ERGER}. In the case where two input pulses represent two consecutive values (e.g. din0=2 and din1=3), t_{D2D} has to be greater than tₘ+t_{c}. If t_{D2D} is smaller than tₘ+t_{c}, either the second input pulse will get “lost” (timing violation) or both pulses will be considered to represent the same value (e.g. din0=2 and din1=2), which is incorrect.

Stretching the “valid” data time window of a cycle is possible with the use of additional JTLs; e.g., if we want the “valid” data time window of a cycle to go from 10 ps to 20 ps, four rather than two JTLs have to be used for the realization of D1ϕ. In one embodiment, this change comes at the cost of area (more JTLs mean more JJs) and performance (each cycle will last longer); but, it results in a much smaller chance of a pulse getting lost in a synchronous component due to imprecision associated with variability or noise. To better understand and quantify the tolerance of our designs to time skew, we perform a number of detailed SPICE-level simulations. These simulations allow us to analyze the sensitivity of temporal gates to pulses under various tD₂D s.

As expected, imprecise pulses do not affect the correct operation of FA, D, and LA, which are implemented with MERGE, JTL, and C-element components; all of these circuits are by nature clockless. The case of INHIBIT is of particular interest though as although its clock signal has been repurposed, still the timing constraints described earlier apply.

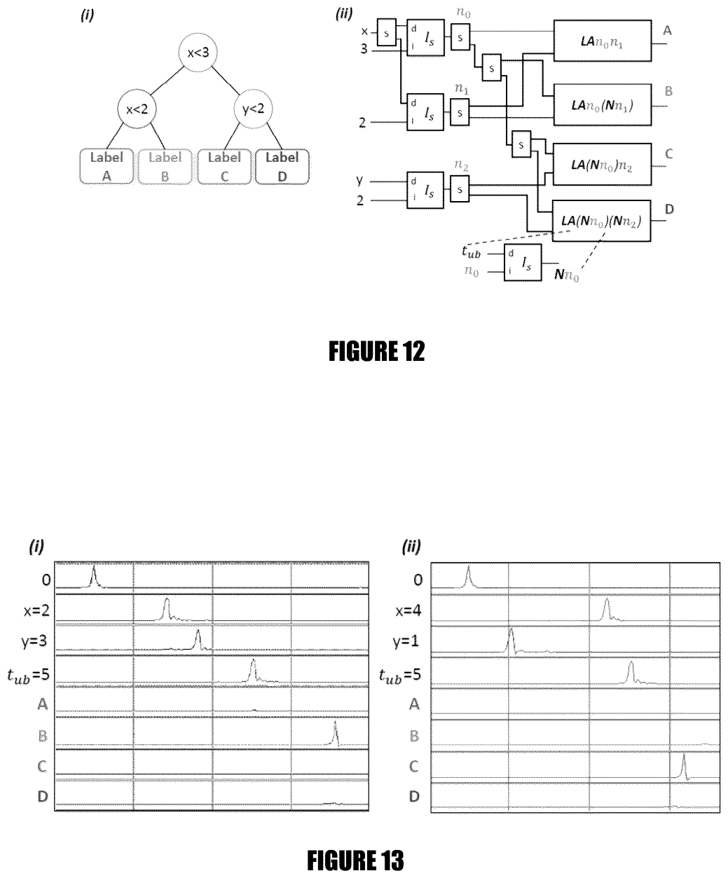

FIG. 7 illustrates timing analysis for an INHIBIT gate and provides simulation results of this case—ψIₛϕ—for various tD₂D s: −5, 0, and 2 ps. As can be seen, if ψ arrives 5 ps before ϕ, the output of the INHIBIT gate remains “0” (the correct value), while an output spike gets produced for tD₂D>−5 ps. So, if two input pulses representing two different values are always more than 5 ps apart, INHIBIT is guaranteed to work as expected. However, if two variables have the same value, D1x has to be greater than 5 ps and the data input pulse ϕ may need to be delayed—so it will appear towards the end of the assigned interval—in order to avoid the occurrence of an undesired output pulse.

For the verification of more complex designs under timing uncertainty, the formalism introduced earlier may be used. Besides model checking, with the help of the proposed function E(s,t) events occurrences can be translated to numbers and incorporated into an interval analysis. Such an analysis is beyond the scope of this disclosure; however, we foresee its potential for the reasoning of superconducting temporal designs in noisy settings, where understanding (and quantifying) how timing skews add up may be critical for the correct behavior and efficiency of the system.

### Proof-of-Concept

As a proof-of-concept, we design and simulate temporal RSFQ accelerators for (a) DNA sequencing, (b) decision trees, and (c) arbitrary function tables. “Race” decision trees are an interesting application. Race trees demonstrate the utility of temporal logic to classification problems. For the realization of their decoders the use of a NOT gate is required; NOT is not one of temporal logic's primitives and its functionality in the temporal domain is different than in Boolean logic. Finally, in contrast to these two designs that are purely asynchronous, for the implementation of the circuit realizing an arbitrary function table the use of both synchronous and asynchronous components is needed, providing a great opportunity to showcase the effectiveness of our data-driven self-timing scheme.

### Needleman-Wunsch Sequence Alignment

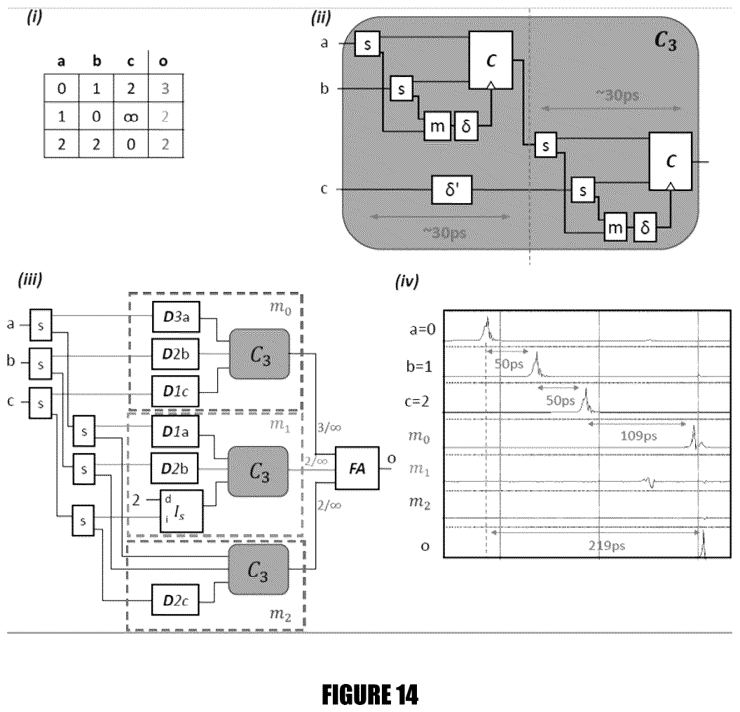

Needleman and Wunsch's algorithm was one of the first applications of dynamic programming to compare biological sequences. The algorithm assigns a score to every possible alignment and its purpose is to find all possible alignments having the highest score. In more detail, the main idea behind this algorithm is that initially a 2D grid will be constructed out of two arbitrary strings P and Q—FIG. 8 (i)—and then, for each individual pair of letters a score will be chosen; each operation—deletion, insertion, match—is associated with a different directed edge, where each edge can have its own score/weight.

In the algorithm's temporal realization, each score associates to a delay. Hence, the total time required for a single “pulse” to propagate from the array's input to the output reveals the desired similarity score. The architecture of this circuit can be generally thought of as a systolic array, where each cell is implemented in RSFQ, as shown in FIG. 8 (iii); FIG. 8 (ii) shows its CMOS implementation. The penalties for deletion, insertion, and match are in the shown example set to 1.

In contrast to the synchronous CMOS case, where the similarity score is incremented by one as the first arriving pulse goes through a flip-flop, in the described asynchronous RSFQ implementation, D1x matches the propagation delay of each unit cell. Thus, every time a pulse goes through a unit cell the score will increment by one. To control the propagation of a pulse across the diagonal, which should happen only when a match occurs, a JJ is used. The switching operation is performed by changing the value of the bias current applied to the JJ; if the current is too low, an incoming RSFQ pulse cannot cause the JJ to fire, which allows for the CMOS control of the circuit.

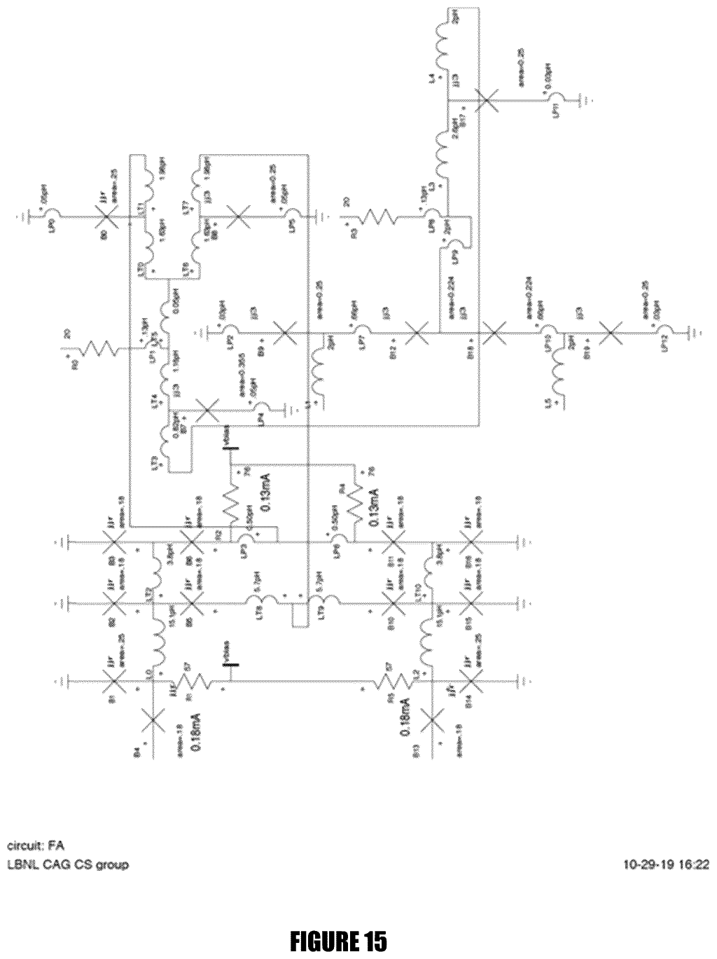

FIG. 9 illustrates shortest path and simulation results for a 3×3 DNA sequence alignment problem. Panel (i): P=ACT and Q=ACT. Panel (ii): P=ACT and Q=GAT. In Panel (i), P=ACT and Q=ACT are compared. Considering that the two strings perfectly match, the shortest path from the grid's input to output cell will be across its diagonal—consisting of four unit cells—and results in a delay of 153 ps. In Panel (ii), where the strings P=ACT and Q=GAT are compared, the propagation delay of a pulse across the grid is 192 ps; the shortest path now consists of five rather than four unit cells. These results match our expectations; in our experiments, the penalties for deletion, insertion, and match are set to 1 and correspond to a 38 ps delay—equal to the propagation delay of each unit cell.

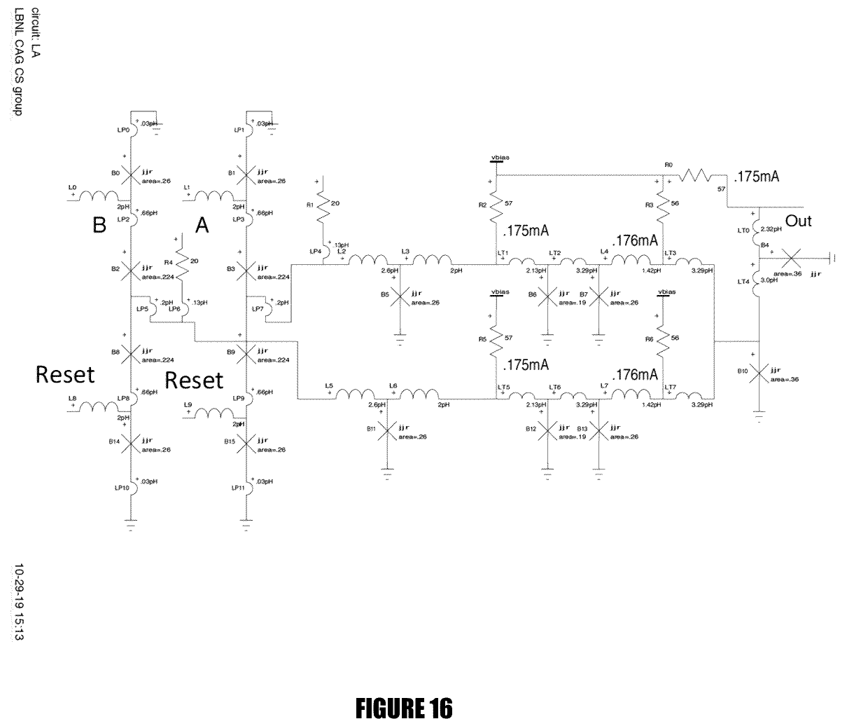

FIG. 10 illustrates: Panel (i): schematic of an RSFQ MERGE element realizing a stateless FIRSTARRIVal gate. Panel (ii): WRSPICE simulation results. In some cases, where race logic constraints can be safely relaxed, superconducting hardware can also provide a trade-off space that enables optimization for select parameters, such as area, latency, power consumption, and complexity (which can play a role in the susceptibility of the circuit to variability). One example of this can be employed in the sequencing accelerator, in which a stateless FIRSTARRIVal gate—composed of just a MERGER, as depicted in FIG. 10—may be used as an alternative to the stateful version presented above. The outcome is an accelerator with fewer JJs (28 rather than 36 JJs are now required per unit cell) and a 14% lower latency. Corresponding simulation results for the two example cases discussed above are shown in FIG. 10.

More performance results and a comparison between RSFQ sequencing accelerators and their CMOS counterparts can be found in Table 3.

TABLE 3
Estimated (best and worst) latency results for DNA sequencing
accelerator in both CMOS (0.5 μm) and RSFQ.

| Strings | CMOS | RSFQ Latency | Improv. | RSFQ Latency | Improv. |
|---|---|---|---|---|---|
| Length | Latency | w/stateful FAs | w/stateful FAs | w/stateless FAs | w/stateless FAs |
| 40 | 50 ns-100 ns | 1.6 ns-3.1 ns | ~32× | 1.4 ns-2.7 ns | ~37× |
| 60 | 75 ns-150 ns | 2.3 ns-4.6 ns | ~32× | 2 ns-4 ng | ~37× |
| 80 | 100 ns-200 ns | 3.1 ns-6.2 ns | ~32× | 2.7 as-5.4 ns | ~37× |

It should be noted that while replacing one or more of the basic temporal RSFQ primitives with simpler ones may in some cases be appealing, it is not always safe. For example, when using a plain MERGER as a FIRSTARRIVal gate, more than one output pulses may be generated, which violates race logic's constraint for the existence of at most one pulse per “wire”. In the case of the sequencing accelerator, this “relaxation” does not cause any malfunction. However, if, for example, COINCIDENCE or INHIBIT gates followed a MERGE-based FIRSTARRIVal gate then the possibility of an error exists; the first spike coming out of a FIRSTARRIVal or a DELAy gate is always valid, this is not the case though for all gates. To verify whether such a replacement is safe or not the formalism introduced in Section 3.2 can be used.

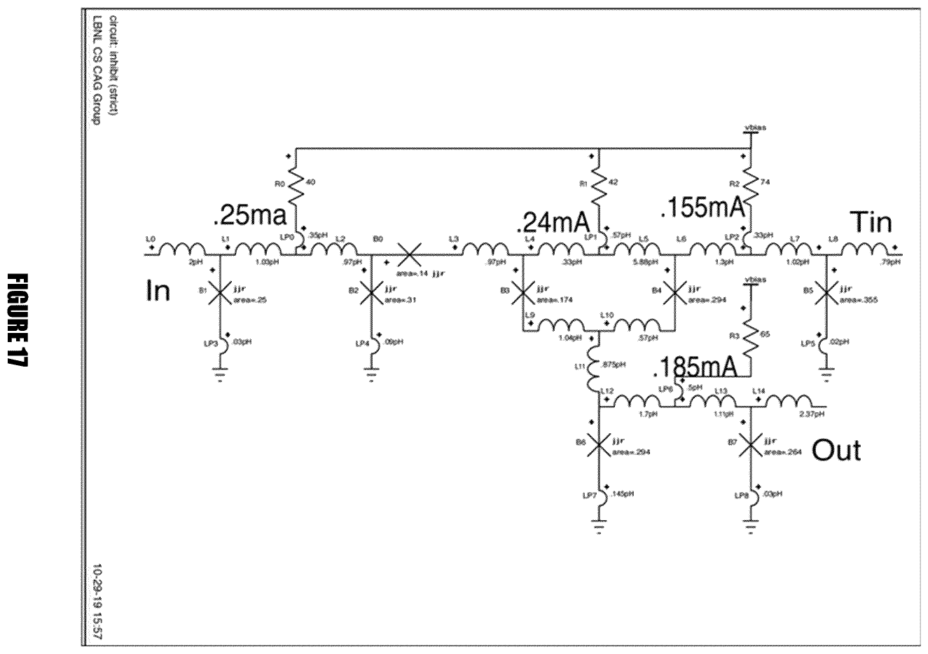

FIG. 11 illustrates simulation results for a stateless implementation of the sequencing accelerator depicted in FIGS. 8 and 9. Panel (i): P=ACT and Q=ACT. Panel (ii): P=ACT and Q=GAT.

### Race Trees

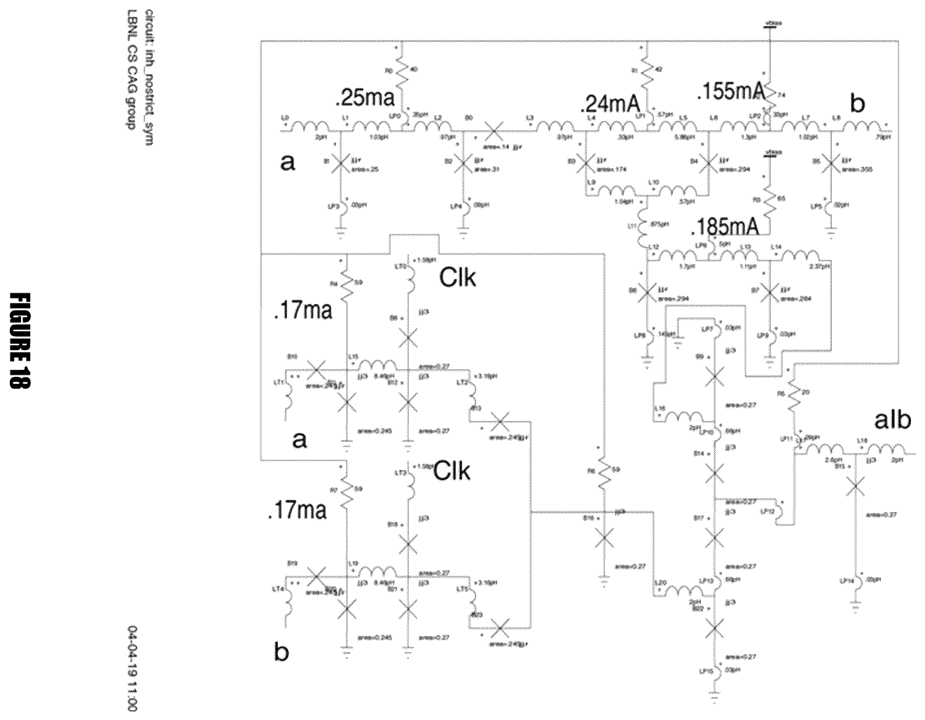

FIG. 12 illustrates: Panel (i): a decision tree with three nodes. Panel (ii): temporal RSFQ implementation of that tree. In a variety of embodiments, an ensemble of decision trees can be implemented in race logic. In the case of Race Trees, each tree node can be considered an independent temporal threshold function and be realized with a single INHIBIT operator.

FIG. 12 (ii) shows the RSFQ equivalent of a CMOS implementation provided herein—realizing the decision tree shown in FIG. 12 (i). For the design of the “label” decoder, the use of a NOT gate is required. In contrast to Boolean logic though, NOT is not a primitive temporal operator. For its construction, we use INHIBIT and an upper bound reference signal t_{ub}, which denotes the end of a specific time interval of interest (directly related to the inputs resolution in this case). Hence, NOT will fire at t=t_{ub} if and only if the gate has received no input spikes from time reference 0 until that moment.

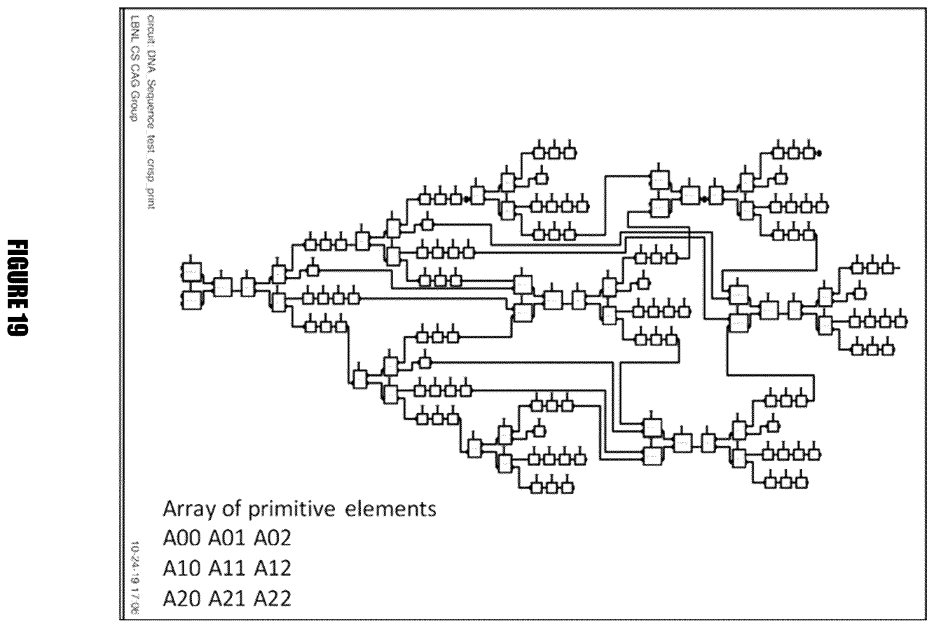

FIG. 13 illustrates: Panel (i): WRSPICE simulation results for x=2, y=3, and t_{ub}=5. Panel (ii): WRSPICE simulation results for x=4, y=1, and t_{ub}=5.

WRSPICE simulation results are provided in FIG. 13. In the first case, inputs x and y are equal to 2 and 3, while in the second one, x and y are set to 4 and 1. Moreover, the upper bound reference signal t_{ub} is set to 5 and D1x corresponds to a 25 ps delay. Associating a smaller delay with D1x may be possible. As expected, the final outcome is Label B for the former and Label C for the latter. The total latency is 150 ps and the design consists of 166 JJs.

More performance results and a comparison with its CMOS counterpart can be found in Table 4.

TABLE 4
Estimated latency results for hardwired Race Trees in both
CMOS (f = 1 GHz) and RSFQ (D1x = 25 ps).

| | | | CMOS | RSFQ | |
|---|---|---|---|---|---|
| # Trees | Depth | Inp. res. | Latency | Latency | Improvement |
| 1 | 6 | 4 bits | 17 ns | 0.464 ns | 37× |
| 1 | 6 | 8 bits | 257 ns | 6.464 ns | 40× |
| 1 | 8 | 4 bits | 17 ns | 0.490 ns | 35× |
| 1 | 8 | 8 bits | 257 ns | 6.490 ns | 40× |

### Arbitrary Function Table

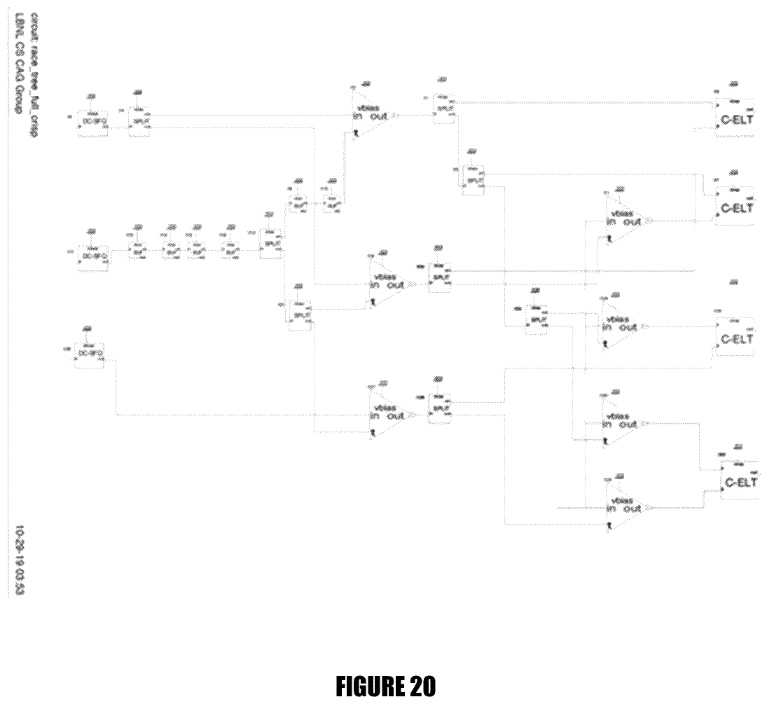

The feedforward temporal network previously described is implemented below. FIG. 14 (i) provides the specification of the example feedforward temporal network. Considering that the function has three input variables and given the limited fan-in of the basic operators, the main building block C₃ (shown in FIG. 14 (ii)) of the architecture (shown in FIG. 14 (iii)) will consist of two 2-ary COINCIDENCE gates; in contrast to the original design, where COINCIDENCE consists of LASTAR-RIVAL, FIRSTARRIVal, INHIBIT, and DELAy gates, we opt for the AND gate-based implementation described in Section 4.1.

For its clocking, apply the data-driven self-timing scheme proposed in Section 4.2 may be applied. To successfully handle time-skewed inputs a delay δ=10 ps is introduced after each MERGER. A delay element δ′ is also used to balance the delays of the two parallel paths that feed the second COINCIDENCE gate.

Simulation results can be found in FIG. 14 (iv). In the simulation, D1x is set to 50 ps and the inputs provided are a=0, b=1, and c=2. As expected, a spike will appear at the output of the upper block m₀, colored in red, at t=209 ps and will go through the succeeding 3-input FIRSTARRIVal gate (stateless rather than stateful FIRSTARRIVal gates are used again); the propagation delay of C₃ is 60 ps, so if we subtract that from the total delay we will end up with 149 ps of delay which corresponds to the desired value 3. No spikes will come out of the other two “blocks”, colored in blue and green, corresponding to two bottom entries of the function table. The circuit design consists of 565 JJs and its latency is 219 ps.

As described, with respect to FIG. 14: Panel (i): specification of an example function table. Panel (ii): Block diagram of a self-timed 3-input CpINCIDENCE gate. Panel (iii): Block diagram showing the accelerator's architecture. Panel (iv): WRSPICE simulation results for a=0, b=1, and c=2.

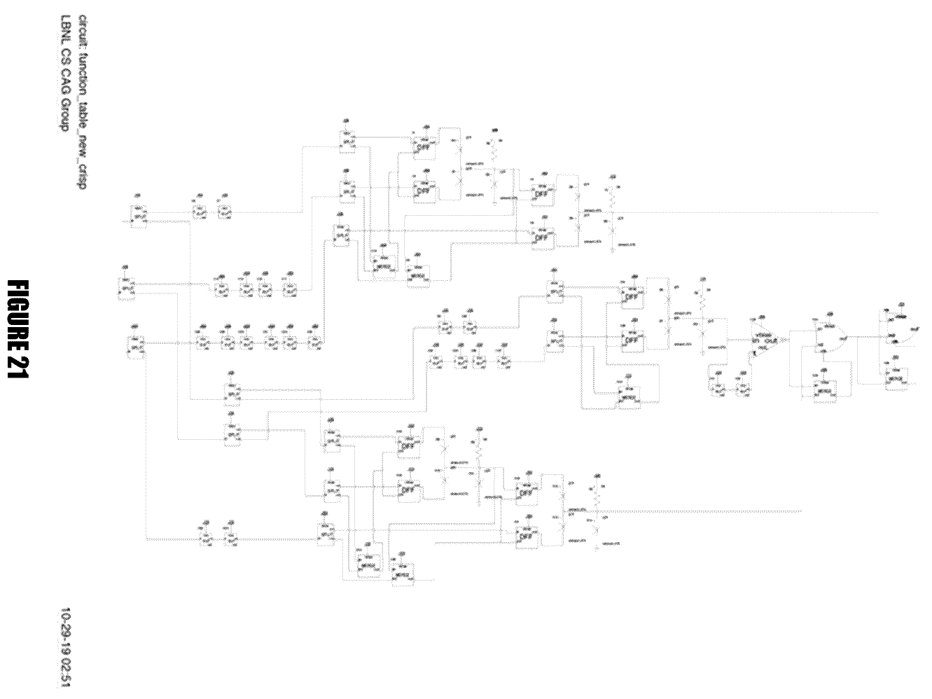

The following example circuits are described with respect to FIGS. 15-21. Presented are example circuit designs of multiple race logic element primitives and example accelerators/circuit designs built using those primitives. The list of the new circuits realizing the race logic primitives are: RSFQ circuit design for the First Arrival Primitive, RSFQ circuit design for the Last Arrival Primitive, RSFQ circuit design for Inhibit Primitive (non-strict), and RSFQ circuit design of Inhibit primitive (strict). Next, three example accelerator/larger logic block blocks are built using the above primitives, namely: RSFQ circuit design for 3×3 DNA accelerator array, RSFQ circuit design for Race Tree, and RSFQ circuit design for Delay Function Table.

Detailed descriptions of these new design inventions are provided next. The circuits built may be derived from the SUNY RSFQ primitives merely as an example. In various embodiments, the circuits may be implemented to realize the race logic functionality with the following new capabilities: the proposed design has reset capability; and asynchronous execution by using synchronous clock signal as one of the data input signal of the race logic primitive (ex. Inhibit race logic primitive is realized/implemented using synchronous inverter design).

FIGS. 15-21 illustrate example circuit implementations, according to one embodiment. It should be noted that the design and description corresponding to FIGS. 15-21 are not the same (e.g., they are other designs of the same primitives) as the ones previously mentioned, such as those in paragraph 66 with respect to FIG. 2 and in paragraph 100 with respect to FIG. 8

FIG. 15 illustrates an example first arrival gate. The first Arrival gate shown in FIG. 15 is built in the same manner as a synchronous OR gate in RSFQ built for Boolean logic with two DC Squids connected in parallel to each other to enable the flow of flux through either of them when there is an input pulse on either one of these squids.

The conventional OR gate in RSFQ holds the state of the flux until the clock signal arrives and generates a pulse after that. In our design, another extra input signal is added called “Reset” as shown in the FIG. 1 which can also activate/reset the state of the flux stored in this gate in the similar fashion as the clock pulse signal. This signal is necessary to reset the first arrival gate in the race logic circuit operations otherwise the first arrival gate will hold the past signal more than the valid computation time.

FIG. 16 illustrates an example Last Arrival Gate using RSFQ. FIG. 16 shows an example circuit design of the second Race logic primitive called Last Arrival gate. This primitive may be realized as an asynchronous gate and used as a C-element in Boolean logic circuits and does not have a clock signal. In the proposed design, two reset signals to reset the state of the circuit is introduced. This way, we can reset this asynchronous gate primitive during the spacer period of the race logic circuit execution.

FIG. 17 illustrates and example Inhibit (strict) Gate using RSFQ. The strict inhibit primitive in race logic has the functionality of inhibiting a one input signal using the second signal. In this invention, this functionality is implemented using a boolean inverter gate built in RSFQ by adding extra delay to allow for the proper inhibition of the signal of interest. Another aspect of this disclosure is that, the clock signal of the inverter may be used as the data/input signal, which is the inhibiting signal.

FIG. 18 illustrates an example Inhibit (non-strict) Gate using RSFQ. FIG. 18 shows an example inhibit (non-strict) race logic primitive implemented as a RSFQ gate. This gate is an extension of the inhibit circuit but implementing the non-strict behavior of the inhibit primitive. The embodiment in this circuit focuses on implementing a new gate in RSFQ circuit which, realizes the non-strict behavior. This is the first time this non-strict inhibit gate has been implemented in RSFQ.

FIG. 19 illustrates an example 3×3 array of DNA Accelerator using RSFQ. Here is demonstrated an RSFQ implementation of Needleman and Wunsch's DNA sequence algorithm with our superconducting temporal logic. The architecture of this circuit can be generally be thought of as a systolic array, where each cell is implemented using various delay elements and merge and forks. Rather than using costly synchronous components for the implementation of our circuit we opt again for asynchronous ones. A MERGE gate functions as a “tying together” of two superconducting input lines.

Whichever input arrives first passes through the MERGE gate and presents itself at the output. This functions as first arrival selection but with a slight modification. Not only does the first pulse pass through, but so do the second and following pulses. If both pulses arrive at the same time, one of the pulses gets swallowed and only a single pulse is propagated. This allows for the detection of not just the first-arrival but the k-first- arrivals. It should be noted that the multiplexing operation for the diagonal signals is performed by changing the value of the current in the first branch of the Josephson Transmission Line (JTL). If the current is too low, an incoming RSFQ pulse will not cause the JTL to fire, which allows for CMOS control of the MUX circuit. The 3×3 array built to implement this accelerator in RSFQ is shown in FIG. 5. Any circuits of size nxn array are contemplated herein.

FIG. 20 illustrates an example Race Tree using RSFQ. Flat Trees are the decision trees, where each tree node is considered an independent temporal threshold function and it can be realized with a single INHIBIT operator. Processing in that case happens in a parallel way and each path from the tree root to a leaf corresponds to a unique conjunction of these attribute tests.

The RSFQ implementation of the race tree circuit is shown in FIG. 6. This circuit is the implementation of the circuit shown in FIG. 14, which is built using seven inhibit gates and four Last Arrival gates.

FIG. 21 illustrates an example Function Table using RSFQ. In one embodiment, the function table introduced in the concept of space-time algebra is implemented as a RSFQ circuit as shown in FIG. 7. The function table consists of two input signals and one output signal. The functionality defined by the table is dictated by the order of arrival of the input signals.

Depending on the order and delay of the signal arrival, the output pulse is generated at a certain delay. In one embodiment, the circuit was built using the asynchronous design of the logic using synchronous RSFQ AND gates. The clock signals of the synchronous RSFQ AND gate may be clocked using the DDST schemed proposed in this disclosure using merge and fork circuits.

### REFERENCES

Y. Ando, R. Sato, M. Tanaka, K. Takagi, N. Takagi, and A. Fujimaki. 2016. Design and Demonstration of an 8-bit Bit-Serial RSFQ Microprocessor: CORE e4. IEEE Transactions on Applied Superconductivity 26, 5 (August 2016), 1-5. https://doi.org/10.1109/TASC.2016.2565609
D. A. Buck. 1956. The Cryotron-A Superconductive Computer Com-ponent. Proceedings of the IRE 44, 4 (April 1956), 482-493. https://doi.org/10.1109/JRPROC.1956.274927
Ruizhe Cai, Ao Ren, Olivia Chen, Ning Liu, Caiwen Ding, Xuehai Qian, Jie Han, Wenhui Luo, Nobuyuki Yoshikawa, and Yanzhi Wang. 2019. A Stochastic-computing Based Deep Learning Framework
Using Adiabatic Quantum-flux-parametron Superconducting Tech-nology. In Proceedings of the 46th International Symposium on Com-puter Architecture (ISCA '19). ACM, New York, NY, USA, 567-578. https://doi.org/10.1145/3307650.3322270
W. Chen, A. V. Rylyakov, V. Patel, J. E. Lukens, and K. K. Likharev. 1999. Rapid single flux quantum T-flip flop operating up to 770 GHz. IEEE Transactions on Applied Superconductivity 9, 2 (June 1999), 3212-3215. https://doi.org/10.1109/77.783712
Alessandro Cimatti, Marco Roveri, and Daniel Sheridan. 2004. Bounded Verification of Past LTL. In Formal Methods in Computer-Aided Design, Alan J. Hu and Andrew K. Martin (Eds.). Springer Berlin Heidelberg, Berlin, Heidelberg, 245-259.
Z. J. Deng, N. Yoshikawa, S. R. Whiteley, and T. Van Duzer. 1997. Data-driven self-timed RSFQ digital integrated circuit and system. IEEE Transactions on Applied Superconductivity 7, 2 (June 1997), 3634-3637. https://doi.org/10.1109/77.622205
M. Dorojevets, P. Bunyk, and D. Zinoviev. 2001. FLUX chip: design of a 20-GHz 16-bit ultrapipelined RSFQ processor prototype based on 1.75-/spl mu/m LTS technology. IEEE Transactions on Applied Superconductivity 11, 1 (March 2001), 326-332. https://doi.org/10.1109/77.919349
Eby G. Friedman. 1997. High Performance Clock Distribution Networks. Springer US, Boston, MA, 1-4. https://doi.org/10.1007/978-1-4684-8440-3_1
Dov Gabbay. 1989. The declarative past and imperative future. In Tem-poral Logic in Specification, B. Banieqbal, H. Barringer, and A. Pnueli (Eds.). Springer Berlin Heidelberg, Berlin, Heidelberg, 409-448.
Kris Gaj, Eby G. Friedman, and Marc J. Feldman. 1997. Timing of Multi-Gigahertz Rapid Single Flux Quantum Digital Circuits. Journal of VLSI signal processing systems for signal, image and video technology 16, 2 (1 Jun. 1997), 247-276. https://doi.org/10.1023/A:1007903527533
D. S. Holmes, A. M. Kadin, and M. W. Johnson. 2015. Superconducting Computing in Large-Scale Hybrid Systems. Computer 48, 12 (December 2015), 34-42. https://doi.org/10.1109/MC.2015.375
D. S. Holmes, A. L. Ripple, and M. A. Manheimer. 2013. Energy-Efficient Superconducting Computing-Power Budgets and Requirements. IEEE Transactions on Applied Superconductivity 23. 3 (June 2013). 1701610-1701610. https://doi.org/10.1109/TASC.2013.2244634
Whiteley Research Incorporated. 2019. WRspice reference manual. Technical Report. http://www.wrcad.com/manual/wrsmanual.pdf
H. Kamerlingh Onnes. 1911. The resistance of pure mercury at helium temperatures. Commun. Phys. Lab. Univ. Leiden, b 120 (1911).
Hans Kamp. 1968. Tense Logic and the Theory of Linear Order. Ph.D. Dissertation. Ucla.
N. K. Katam, J. Kawa, and M. Pedram. 2019. Challenges and the status of superconducting single flux quantum technology. In 2019 Design, Automation Test in Europe Conference Exhibition (DATE). 1781-1787. https://doi.org/10.23919/DATE.2019.8747356
Konstantin K. Likharev. 2012. Superconductor digital electronics. Physica C: Superconductivity and its Applications 482 (2012), 6-18. https://doi.org/10.1016/j.physc.2012.05.016 2011 Centennial supercon-ductivity conference—EUCAS-ISEC-ICMC.
K. K. Likharev and V. K. Semenov. 1991. RSFQ logic/memory family: a new Josephson-junction technology for sub-terahertz-clock-frequency digital systems. IEEE Transactions on Applied Superconductivity 1, 1 (March 1991), 3-28. https://doi.org/10.1109/77.80745
Advait Madhavan, Timothy Sherwood, and Dmitri Strukov. 2014. Race Logic: A Hardware Acceleration for Dynamic Programming Algo-rithms. SIGARCH Comput. Archit. News 42, 3 (June 2014), 517-528. https://doi.org/10.1145/2678373.2665747
A. Madhavan, T. Sherwood, and D. Strukov. 2017. A 4-mm2 180-nm-CMOS 15-Giga-cell-updates-per-second DNA sequence alignment engine based on asynchronous race conditions. In 2017 IEEE Custom Integrated Circuits Conference (CICC). 1-4. https://doi.org/10.1109/CICC.2017.7993630
   R. Manohar. 2015. Comparing Stochastic and Deterministic Computing. IEEE Computer Architecture Letters 14, 2 (July 2015), 119-122. https://doi.org/10.1109/LCA.2015.2412553
O. A. Mukhanov, S. V. Rylov, V. K. Semonov, and S. V. Vyshenskii. 1989. RSFQ logic arithmetic. IEEE Transactions on Magnetics 25, 2 (March 1989), 857-860. https://doi.org/10.1109/20.92421
M. H. Najafi, D. J. Lilja, M. D. Riedel, and K. Bazargan. 2018. Low-Cost Sorting Network Circuits Using Unary Processing. IEEE Transactions on Very Large Scale Integration (VLSI) Systems 26, 8 (August 2018), 1471-1480.
   https://doi.org/10.1109/TVLSI.2018.2822300
P. Russer. 1971. General energy relations for Josephson junctions. Proc. IEEE 59, 2 (February 1971), 282-283. https://doi.org/10.1109/PROC.1971. 8133
James E. Smith. 2018. Space-Time Algebra: A Model for Neocor-tical Computation. In Proceedings of the 45th Annual International Symposium on Computer Architecture (ISCA '18). IEEE Press, 289-300. https://doi.org/10.1109/ISCA.2018.00033
James E. Smith. 2019. (Newtonian) Space-Time Algebra. arXiv:cs.LO/2001.04242
Igor I Soloviev, Nikolay V Klenov, Sergey V Bakurskiy, Mikhail Yu Kupriyanov, Alexander L Gudkov, and Anatoli S Sidorenko. 2017. Beyond Moore's technologies: operation principles of a supercon-ductor alternative. Beilstein Journal of Nanotechnology 8 (December 2017), 2689-2710. https://doi.org/10.3762/bjnano.8.269
M. Tanaka, R. Sato, Y. Hatanaka, and A. Fujimaki. 2016. High-Density Shift-Register-Based Rapid Single-Flux-Quantum Memory System for Bit-Serial Microprocessors. IEEE Transactions on Applied Superconductivity 26, 5 (August 2016), 1-5. https://doi.org/10.1109/TASC.2016.2555905
G. Tang, P. Qu, X. Ye, and D. Fan. 2018. Logic Design of a 16-bit Bit-Slice Arithmetic Logic Unit for 32-/64-bit RSFQ Microprocessors. IEEE Transactions on Applied Superconductivity 28, 4 (June 2018), 1-5. https://doi.org/10.1109/TASC.2018.2799994
G. Tang, K. Takata, M. Tanaka, A. Fujimaki, K. Takagi, and N. Takagi. 2016. 4-bit Bit-Slice Arithmetic Logic Unit for 32-bit RSFQ Micro-processors. IEEE Transactions on Applied Superconductivity 26, 1 (January 2016), 1-6. https://doi.org/10.1109/TASC.2015.2507125
Swamit S. Tannu, Poulami Das, Michael L. Lewis, Robert Krick, Dou-glas M. Carmean, and Moinuddin K. Qureshi. 2019. A Case for Super-conducting Accelerators. In Proceedings of the 16th ACM International Conference on Computing Frontiers (CF'19). ACM, New York, NY, USA, 67-75. https://doi.org/10.1145/3310273.3321561
Sergey K Tolpygo. 2016. Superconductor digital electronics: Scalability and energy efficiency issues. Low Temperature Physics 42, 5 (2016), 361-379.
Georgios Tzimpragos, Advait Madhavan, Dilip Vasudevan, Dmitri Strukov, and Timothy Sherwood. 2019. Boosted Race Trees for Low Energy Classification. In Proceedings of the Twenty-Fourth International Conference on Architectural Support for Programming Languages and Operating Systems (ASPLOS '19). Association for Computing Machin-ery, New York, NY, USA, 215-228. https://doi.org/10.1145/3297858.3304036
Y. Yamanashi, M. Tanaka, A. Akimoto, H. Park, Y. Kamiya, N. Irie, N. Yoshikawa, A. Fujimaki, H. Terai, and Y. Hashimoto. 2007. Design and Implementation of a Pipelined Bit-Serial SFQ Microprocessor, CORE1β. IEEE Transactions on Applied Superconductivity 17, 2 (June 2007), 474-477. https://doi.org/10.1109/TASC.2007.898606

What is claimed is:

1. A primitive race-logic temporal operator, comprising superconducting logic single flux quantum (SFQ) cells.

2. The temporal operator of claim 1, wherein the temporal operator is a FIRSTARRIVAL operator.

3. The temporal operator of claim 2, wherein the FIRSTARRIVAL operator comprises a merge element.

4. The temporal operator of claim 3, wherein the FIRSTARRIVAL operator further rcomprises a D flip-flop element

5. The temporal operator of claim 1, wherein the temporal operator is a STRICTINHIBIT operator.

6. The temporal operator of claim 5, wherein the STRICTINHIBIT operator comprises an inverter element.

7. The temporal operator of claim 1, wherein the temporal operator is a DELAY operator.

8. The temporal operator of claim 7, wherein the DELAY operator comprises a constant addition element.

9. The temporal operator of claim 1, wherein the temporal operator is a LASTARRIVAL operator.

10. The temporal operator of claim 9, wherein the LASTARRIVAL operator comprises two Superconducting quantum interference devices (SQUIDs).

11. The temporal operator of claim 1, wherein the temporal operator is a COINCIDENCE operator.

12. The temporal operator of claim 11, wherein the COINCIDENCE operator comprises an SFQ AND gate.

13. The temporal operator of claim 1, wherein combining the temporal operator with another temporal operator results in a self-timed superconducting accelerator architecture.

14. The temporal operator of claim 13, wherein operations of the accelerator architecture are performed with a reduced clock tree.

15. The temporal operator of claim 1, wherein the temporal operator is a FIRSTARRIVAL operator, further comprising an INHIBIT operator and a DELAY operator, and wherein the FIRSTARRIVAL, INHIBIT, and DELAY operators are asynchronous.

16. The temporal operator of claim 15, wherein the FIRSTARRIVAL, INHIBIT, and DELAY operators form a set of computational primitives that are functionally complete.

17. The temporal operator of claim 1, wherein the INHIBIT operator comprises a reset element.

18. The temporal operator of claim 1, wherein the superconducting logic SFQ cells are rapid single flux quantum (RSFQ) cells.

19. The temporal operator of claim 1, wherein the superconducting logic SFQ cells are Adiabatic Quantum Flux Parametron (AQFP) cells.

20. The temporal operator of claim 1, further comprising a data-driven self-timing (DDST) scheme, comprising clock signal generated at each gate and a delay element.
